(19) United States
(12) Patent Application Publication
(10) Pub. No.: US 2012/0088030 A1
(43) Pub. Date: Apr. 12, 2012

(54) FILM FORMING APPARATUS, FILM FORMING METHOD, AND RECORDING MEDIUM

(75) Inventors: Hitoshi KATO, Iwate (JP); Yasushi Takeuchi, Iwate (JP)

(73) Assignee: Tokyo Electron Limited, Tokyo (JP)

(21) Appl. No.: 13/238,366

(22) Filed: Sep. 21, 2011

(30) Foreign Application Priority Data
Oct. 7, 2010 (JP) 2010-227624

(51) Int. Cl. C23C 16/455; C23C 16/52; C23C 16/458

(52) U.S. Cl. 427/255.5; 118/719; 118/697

(57) ABSTRACT

A film forming apparatus that produces a thin film by repeating cycles of sequentially supplying reaction gases including a loading table in a vacuum vessel having substrate mounting areas; reaction gas supplying units arranged in a peripheral direction with intervals to supply the reaction gases onto substrates; separating areas separating atmospheres of the processing areas; separation gas supplying units supplying separation gases to render a supply amount to outer peripheral side separation areas greater than a supply amount to center side separation areas; a ceiling face surrounding narrow areas together with the loading table to enable the separation gases flow from the separating areas to the processing areas along the center side separation areas and the outer peripheral side separation areas a vacuum ejecting mechanism; and a rotary mechanism rotating the loading table relative to the reaction gas supplying units and the separating areas.

### CROSS-REFERENCE TO RELATED APPLICATIONS

This patent application is based upon and claims the benefit of priority of Japanese Patent Application No. 2010-227624 filed on Oct. 7, 2010, the entire contents of which are incorporated herein by reference.

### BACKGROUND OF THE INVENTION

1. Field of the Invention

The present invention generally relates to a film forming apparatus, a film forming method, and a recording medium, with which a thin film is formed by sequentially supplying plural reaction gases under a vacuum atmosphere.

2. Description of the Related Art

In forming a thin film such as a silicon oxide (SiO₂) film on a surface of a substrate (hereinafter, referred to as a “wafer”) such as a semiconductor wafer, film forming methods called Atomic Layer Deposition (ALD), Molecular Layer Deposition (MLD) and so on may be used. An apparatus for carrying out the film forming method is disclosed in Patent Documents 1 and 2. Plural processing areas and separating areas, which are provided between the processing areas and supply a separation gas (a purge gas), are arranged in a peripheral direction of a vacuum vessel, and a susceptor is rotated around a vertical axis so that a wafer sequentially passes through the processing areas.

In these apparatuses, the flow rates of the separation gases may be set to be greater than the flow rate of the reaction gas in order to prevent the separation gases from mutually mixing. However, if the separation gas is supplied with a great flow rate, the following problems may be apt to occur. Therefore, it may be preferable to change the supplying amount of the separation gas (reducing the supplying amount of the separation gas) as minimally as possible. Said differently, the separation gas may intrude into the processing area along with the rotation of the susceptor to thereby dilute the reaction gas, depending on process conditions such as a degree of vacuum and a rotational speed of the susceptor. In this case, a time period while the reaction gas is in contact with the wafer may become shorter than a predetermined time period and/or the concentration of the reaction gas with which the wafer is in contact may become shorter than the predetermined concentration to thereby prevent a target film forming rate from being obtained (only a small film forming rate may be obtainable).

If the separation gas of the great flow rate is supplied, the separation gas is exhausted from a vacuum vessel. At this time, a great load maybe applied to the vacuum pump. Meanwhile, there may be a case where a vacuum pump has a great exhausting capability in order to change the load on the vacuum pump as small as possible (reducing the load on the vacuum pump). However, if the load on the vacuum pump is reduced by the great exhausting capability, the cost of the expensive vacuum pump becomes high and therefore the cost of the apparatus for carrying out the film forming method becomes high. Further, if the amount of the separation gas consumed increases, the cost of the separation gas increases.

Therefore, as one tries to increase the film forming rate, said differently as the rotational speed of the susceptor is increased and/or the pressure inside the vacuum vessel is increased while decreasing the degree of vacuum inside the vacuum vessel, the supply amount of the separation gas is increased. Then, the film forming rate is conspicuously decreased and the cost of the apparatus for carrying out the film forming method is conspicuously increased.

Patents Documents 1 and 2 do not disclose these considerations presented by the inventors of the present invention.

### [Patent Document 1]

Japanese Laid-open Patent Publication 2007-247066

### [Patent Document 2]

Japanese Laid-open Patent Publication Hei. 4-187912

### SUMMARY OF THE INVENTION

Accordingly, embodiments of the present invention may provide a novel and useful technique of suppressing an amount of consumption of a separation gas supplied to a separating area interposing between plural processing areas while maintaining a function of separating the processing areas in forming a thin film of a reaction product by rotating a table on which a substrate is mounted, solving one or more of the problems discussed above.

According to an aspect of the present invention, there is provided a film forming apparatus that produces a thin film by repeating cycles of sequentially supplying plural kinds of reaction gases including a loading table which is provided in a vacuum vessel and has substrate mounting areas for mounting substrates thereon; a plurality of reaction gas supplying units which are arranged in a peripheral direction with intervals between the reaction gas supplying units and configured to supply the plural kinds of the reaction gases onto the substrates in the substrate mounting areas; separating areas which are provided between the processing areas and configured to separate atmospheres of the processing areas to which the reaction gases are supplied; separation gas supplying units which are configured to supply separation gases to center side separation areas on a center side of the separation areas and outer peripheral side separation areas on an outer peripheral side of the separation areas inside the separation areas to render a supply amount to the outer peripheral side separation areas greater than a supply amount to the center side separation areas; a ceiling face which surrounds narrow areas together with the loading table to enable the separation gases flow from the separating areas to the processing areas along the center side separation areas and the outer peripheral side separation areas; a vacuum ejecting mechanism configured to form a vacuum inside the vacuum vessel; and a rotary mechanism which rotates the loading table relative to the reaction gas supplying units and the separating areas.

The film forming apparatus may be formed such that the separation gas supplying units are provided to face the substrate mounting areas and have gas nozzles extending along the center side separation areas and the outer peripheral side separation areas, the gas nozzles have a plurality of gas discharge ports for discharging the separation gases to the substrate mounting areas along longitudinal directions of the gas nozzles with an interval between the gas discharge ports, and at least one of the interval between the gas discharge ports, opening diameters of the gas discharge ports, and densities of arranging the gas discharging ports are set to render the supply amount to the outer peripheral side separation areas greater than the supply amount to the center side separation areas.

According to another aspect of the present invention, there is provided a film forming method for forming a thin film by repeating a plurality of cycles of sequentially supplying plural kinds of reaction gases in a vacuum atmosphere including loading substrates on substrate mounting areas for mounting the substrates thereon, the substrate mounting areas being provided inside a vacuum vessel; forming a vacuum inside the vacuum vessel by evacuating the vacuum vessel; supplying separation gases to separating areas between processing areas into which the reaction gases are supplied to render a supply amount to outer peripheral side separation areas on an outer peripheral side of the separation areas greater than a supply amount to center side separation areas on an outer peripheral side of the separation areas; supplying the plural kinds of the reaction gases onto the substrate mounting areas from a plurality of reaction gas supplying units which are arranged in a peripheral direction with intervals between the reaction gas supplying units; separating atmospheres of the processing areas via narrow areas surrounding a ceiling face and a loading table inside the separating areas by discharging the separation gases from the separating areas to the processing areas along the outer peripheral side separation areas and the center side separation areas; and rotating the loading table relative to the reaction gas supplying units and the separating areas to sequentially positioning the substrates in the processing areas via the separating areas. The film forming method may be formed such that a pressure inside the vacuum vessel is 133 Pa or more, and a rotational speed of rotating the loading table relative to the reaction gas supplying units and the separating areas is 20 rpm or more

According to another aspect of the present invention, there is provided a computer-readable, non-transitory medium storing a program that is used in a film forming apparatus that produces a thin film by repeating cycles of sequentially supplying plural kinds of reaction gases and causes a target computer to perform a procedure including loading substrates on substrate mounting areas for mounting the substrates thereon, the substrate mounting areas being provided inside a vacuum vessel; forming a vacuum inside the vacuum vessel by evacuating the vacuum vessel; supplying separation gases to separating areas between processing areas into which the reaction gases are supplied to render a supply amount to outer peripheral side separation areas on an outer peripheral side of the separation areas greater than a supply amount to center side separation areas on an outer peripheral side of the separation areas; supplying the plural kinds of the reaction gases onto the substrate mounting areas from a plurality of reaction gas supplying units which are arranged in a peripheral direction with intervals between the reaction gas supplying units; separating atmospheres of the processing areas via narrow areas surrounding a ceiling face and a loading table inside the separating areas by discharging the separation gases from the separating areas to the processing areas along the outer peripheral side separation areas and the center side separation areas; and rotating the loading table relative to the reaction gas supplying units and the separating areas to sequentially positioning the substrates in the processing areas via the separating areas.

The computer-readable, non-transitory medium according to may be formed such that a pressure inside the vacuum vessel is 133 Pa or more, and a rotational speed of rotating the loading table relative to the reaction gas supplying units and the separating areas is 20 rpm or more.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view of an example of a film forming apparatus of embodiments of the present invention taken along a line I-I′ of FIG. 3;

FIG. 2 is a perspective view schematically illustrating an inside of the film forming apparatus;

FIG. 3 is a cross-sectional plan view of the image forming apparatus;

FIG. 4 is a vertical cross-sectional view schematically illustrating the inside of the film forming apparatus by outwardly viewing from an inside of the film forming apparatus;

FIG. 5 is an enlarged plan view illustrating a part of the inside of the film forming apparatus;

FIG. 6 is a vertical cross-sectional view illustrating a part of the inside of the film forming apparatus;

FIG. 7 is an enlarged plan view illustrating a part of the inside of the film forming apparatus;

FIG. 8 is a vertical cross-sectional view illustrating a part of the inside of the film forming apparatus;

FIG. 9 is a vertical cross-sectional view illustrating a part of the inside of the film forming apparatus;

FIG. 10 is a horizontal cross-sectional view of the film forming apparatus schematically illustrating gas flows inside the film forming apparatus;

FIG. 11 is a characteristic diagram schematically illustrating the supply amount of a separation gas supplied to the separating area of the film forming apparatus;

FIG. 12 is a vertical cross-sectional view illustrating apart of the inside of another example of the film forming apparatus;

FIG. 13 is a vertical cross-sectional view illustrating apart of the inside of another example of the film forming apparatus;

FIG. 14 is a plan view illustrating a part of the inside of the other example of the film forming apparatus; and

FIG. 15 is a plan view illustrating a part of the inside of the other example of the film forming apparatus.

### DETAILED DESCRIPTION OF THE PREFERRED EMBODIMENTS

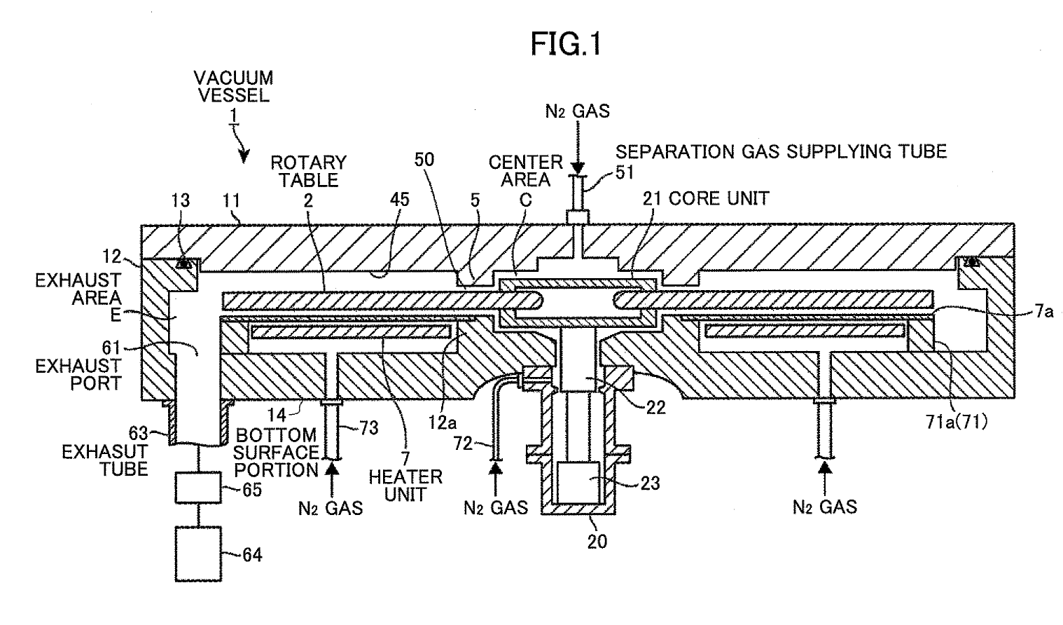

A description is given below, with reference to the FIG. 1 through FIG. 15 of embodiments of the present invention.

In the embodiments described below, the reference symbols typically designate as follows:
W: wafer;
1: vacuum vessel;
2: rotary table;
4: sector-like portion;
D: separating area;
24: recessed portion;
31: first reaction gas nozzle;
32: second reaction gas nozzle;
41, 42: separation gas nozzle;
33: discharge port;
P1: processing area; and
P2: processing area

Referring to FIG. 1 to FIG. 9, the film forming apparatus of the embodiments is described. Although cross-sectional views of some of main components of the film forming apparatus are indicated by hatching ordinarily used for metals, the materials of some of the main components are not limited to the metals. The film forming apparatus includes a flat vacuum vessel 1 of which plan view is substantially a circle and a rotary table 2 being a loading table which has a rotation center at the center of the vacuum vessel 1 and provided in the vacuum vessel 1. The vacuum vessel 1 is formed so that the ceiling 11 is attachable to and detachable from the container body 12. By reducing the pressure inside the vacuum vessel 1, the ceiling 11 is suctioned to the container body 12 interposing a sealing member which is formed like a ring and provided at a peripheral portion of an upper surface of the container body 12 such as an O-ring 13 to maintain a gas tight state. However, the ceiling is lifted upward by a driving mechanism (not illustrated) when the ceiling 11 is separated from the container body 12.

The rotary table 2 is fixed by a core unit 21 in a cylindrical shape at the center portion. The core unit is fixed to the upper end of the rotary shaft 22 extending in the vertical direction. The rotary shaft 22 penetrates a bottom surface portion 14 of the vacuum vessel 1. The lower end of the rotary shaft is connected to a driving unit 23 which is a rotary mechanism for rotating the rotary shaft 22 around a vertical axis of the rotary shaft 22. For example, the direction of rotating the rotary shaft is in the clockwise direction. The rotary shaft 22 and the driving unit 23 are accommodated in a cylindrical casing 20 of which upper surface is opened. A flange on the upper surface of the casing 20 is hermetically attached to the lower surface of a bottom surface portion 14 of the vacuum vessel 1 to maintain the gastight state between the inner atmosphere and the outer atmosphere of the casing 20.

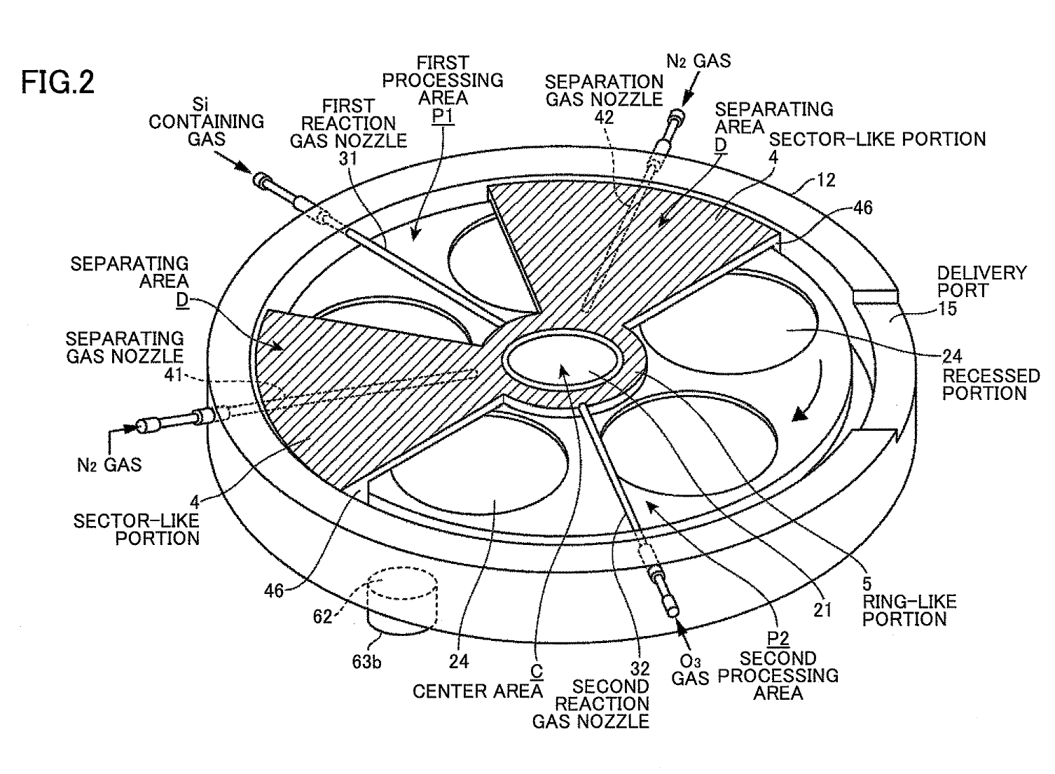

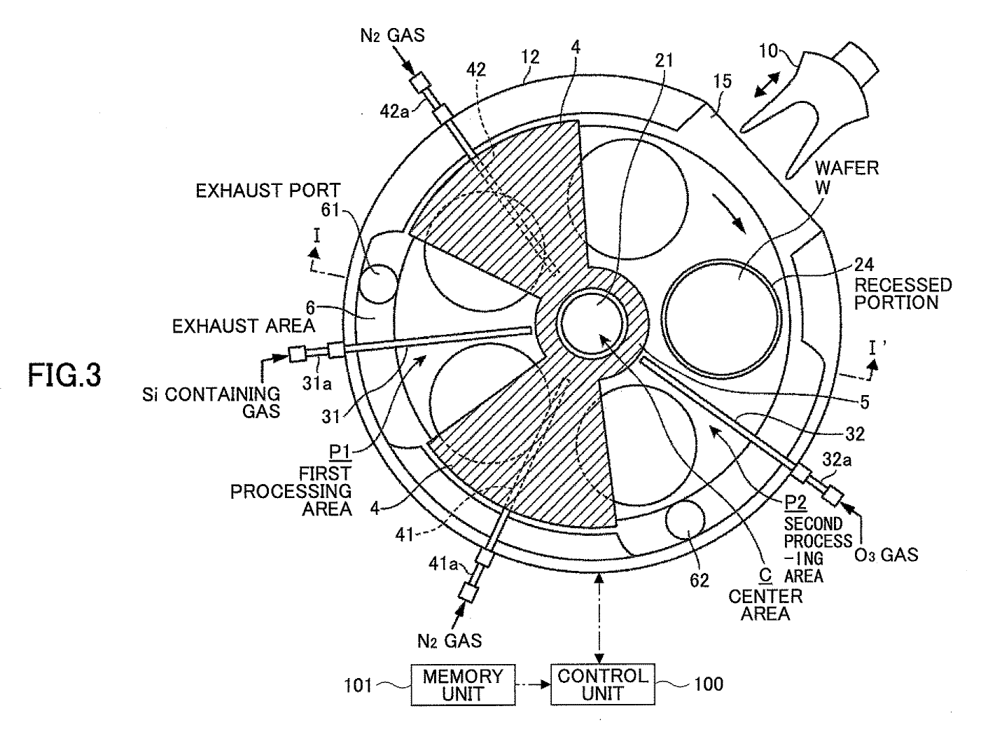

Referring to FIG. 2 and FIG. 3, recessed portions 24 in a circular shape are provided on the surface of the rotary table 2 to mount plural semiconductor substrates, being semiconductor wafers (hereinafter, referred to as wafers) along the rotary direction of the rotary table 2. The number of the wafers is, for example, five. In a plan view, a distance between the rotation center of the rotary table 2 and end portions of the recessed portions 24 on the rotation center sides is, for example, 160 mm, and a distance between the outer peripheral portion of the rotary table 2 and end portions of the recessed portions 24 on the outer edge sides is, for example, 30 mm. The diameter of the wafer W is, for example, 300 mm. Referring to FIG. 3, the wafer W is illustrated for only one recessed portion 24 for simplicity.

The diameter of the recessed portion 24 is slightly larger then the diameter of the wafer W by, for example, 4 mm. The depth of the recessed portion is about the thickness of the wafer W. Therefore, if the wafer W is dropped into the recessed portion 24, the surfaces of the wafers W in a region where the wafers are not mounted and the surface of the rotary table becomes substantially flat. Through holes (not illustrated) through which lift pins for lifting up and down the back surfaces of the wafers by supporting the back surface may penetrate the bottom surfaces of the recessed portions 24. The number of the lift pins may be three. The recessed portions 24 are provided to prevent the wafers W from jumping out of the rotary table with a centrifugal force caused by the rotation of the rotary table by positioning the wafers W. The recessed portions 24 correspond to a substrate mounting area.

Referring to FIG. 2 and FIG. 3, a first reaction gas nozzle 31, a second reaction gas nozzle 32, and two separation gas nozzles 41, 42 made of, for example, quartz are radially arranged at positions of the rotary table 2 facing the recessed portions 24. The first reaction gas nozzle 31, the second reaction gas nozzle 32, and the two separation gas nozzles 41, 42 may be arranged interposing gaps in the peripheral direction (a rotational direction of the rotary table 2) of the vacuum vessel 1. In this example, the second reaction gas nozzle 32, the separation gas nozzle 41, the first reaction gas nozzle 31 and the separation gas nozzle 42 are arranged in this order in the clockwise direction when viewed from a delivery port 15 (described later) For example, these nozzles 31, 32, 41 and 42 may be attached to the outer peripheral wall of the vacuum vessel so as to horizontally extend to the rotation center of the rotary table. Gas introducing ports 31a, 32a, 41a, and 42a positioned at the ends of the nozzles 31, 32, 41 and 42 penetrate the outer peripheral wall of the vacuum vessel 1. These reaction gas nozzles 31 and 32 form a first gas supplying unit and a second gas supplying unit, respectively. The separation gas nozzles 41, 42 form separation gas supplying units, respectively.

The first reaction gas nozzle 31 is connected to a gas supplying source (not illustrated) of a first reaction gas containing silicon (Si) via a flow rate adjusting valve and so on. For example, the first reaction gas may be a di-isopropylaminosilane gas, a bis(tertiary-butylaminosilane) (BTBAS) gas, and a SiH2(NH—C(CH3)3)2) gas. The second reaction gas nozzle 32 is connected to a gas supplying source (not illustrated) of a mixed gas of an O3 (ozone) gas and an O2 (oxygen) gas via a flow rate adjusting valve and so on in a similar manner thereto. The flow rates of the first reaction gas and the second reaction gas may be about 10 to 1000 sccm and about 1 to 10 slm, respectively. The first reaction gas and the second reaction gas may be the above-mentioned gases and gases listed in the following table to form thin films listed in the right column, or the reaction gases maybe combined to form a mixture or a laminated body of the thin films. Further, if an O3 gas is used as the second reaction gas, an oxygen (O) plasma may be used instead of the O3 gas or in addition to the O3 gas.

TABLE

| FIRST | SECOND | TYPE OF FILM |
|---|---|---|
| REACTION GAS | REACTION GAS | (THIN FILM) |
| DICHLOROSILANE | AMMONIA GAS | SILICON NITRIDE |
| (DCS) GAS | (NH3) GAS | (SiN) FILM |
| TRIMETHYLALUMINUM | O3 GAS | ALUMINUM OXIDE |
| (TMA) GAS | | (Al2O3) FILM |
| TETRAKIS(ETHYLMETHYLAMINO) | O3 GAS | ZIRCONIUM OXIDE |
| ZIRCONIUM | | (ZrO2) FILM |
| (TEMAZr) GAS | | |
| TETRAKIS(ETHYLMETHYLAMINO) | O3 GAS | HAFNIUM OXIDE |
| HAFNIUM | | (HfO2) FILM |
| (TEMAH) GAS | | |
| STRONTIUMBIS- | O3 GAS | STRONTIUM OXIDE |
| TETRAMETHYLHEPTANEDIONATO | | (SrO) FILM |
| (Sr(THD)2) GAS | | |
| TITANIUMMETHYLPENTANEDIONATOBIS- | O3 GAS | TITANIUM OXIDE |
| TETRAMETHYLHEPTANEDIONATO | | (TiO2) FILM |
| (Ti(MPD)(TIID)) GAS | | |

The separation gas nozzles 41 and 42 are connected to corresponding gas supplying sources (not illustrated) of a nitrogen (N2) gas, being the separation gas, via corresponding flow rate adjusting valves. The flow rates of the separation gases discharged from the separation gas nozzles 41, 42 are, for example, about 1 slm to about 20 slm, respectively. Hereinafter, an example that the second reaction gas is an O3 gas is described merely for convenience.

The reaction gas nozzles 31, 32 have gas discharge ports 33 which are downwardly directed and formed with equal intervals of, for example, 10 mm along the longitudinal direction of the reaction gas nozzles 31, 32. An area lower than the reaction gas nozzles 31 and 32 become a first processing area P1 for causing the wafers W to absorb the Si containing gas and a second processing area P2 where the absorbed Si containing gas reacts with the O3 gas. The reaction gas nozzles 31 and 32 are apart from the ceiling face 45 in the processing areas P1 and P2 and provided in the vicinity of the wafer W.

The separation gas nozzles 41 and 42 are provided to separate the first processing area P1 from the second processing area P2. Plural gas discharge ports 33 having an opening size, i.e. a diameter of 0.3 or 0.5 mm, are formed at plural positions on a lower surface of the separation gas nozzles 41 and 42 in the longitudinal direction of the separation gas nozzles 41 and 42. The interval (pitch) between the gas discharge ports 33, 33 is shorter on the center side of the rotary table of the separation gas nozzle in the longitudinal direction than on the outer peripheral side of the rotary table of the separation gas nozzle. Fore-ends of these nozzles 31, 32, 41 and 42 are arranged so as to protrude on the center side of the rotary table by, for example, about 20 mm or 40 mm from the outer edges of the recessed portions.

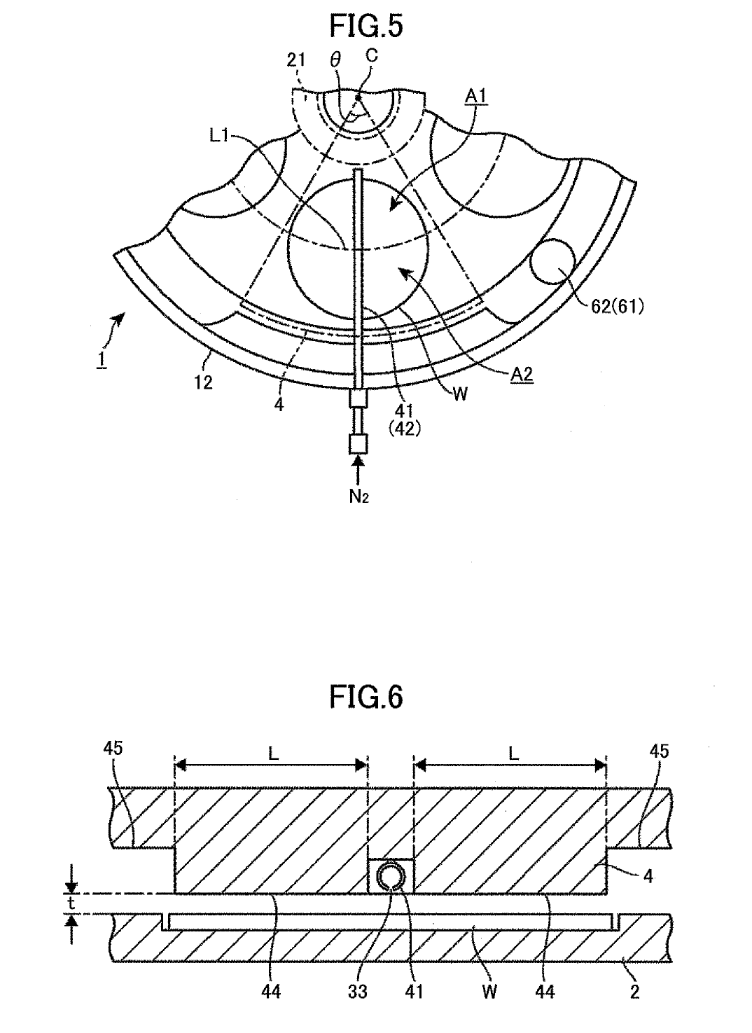

Referring to FIG. 2 and FIG. 3, sector-like portions 4 of a sector-like plan view downwardly protruding are provided in the ceiling 11 of the vacuum vessel 1 in the separating areas D. The sector-like portions 4 are formed around the rotation center of the rotary table, and shaped as if a circle along and in the vicinity of the inner peripheral wall of the vacuum vessel 1 is divided in the peripheral direction. The separation gas nozzles 41 and 42 are accommodated in grooves 43 in the sector-like portions 4. The grooves 43 accommodating the separation gas nozzles 41 and 42 extend in radius directions substantially from centers of the outer peripheries of the sector-like portions 4. Referring to FIG. 5, an angle e formed among the rotation center of the rotary table 2 in its plan view and two ends of the outer periphery of the sector-like portion 4 in its plan view is, for example, 60°. Referring to FIG. 6, a distance t between the wafers W on the rotary table 2 and the lower surface of the sector-like portion 4 is, for example, 4 mm. Referring to FIG. 5, the sector-like portion 4 is schematically illustrated by a dot chain line.

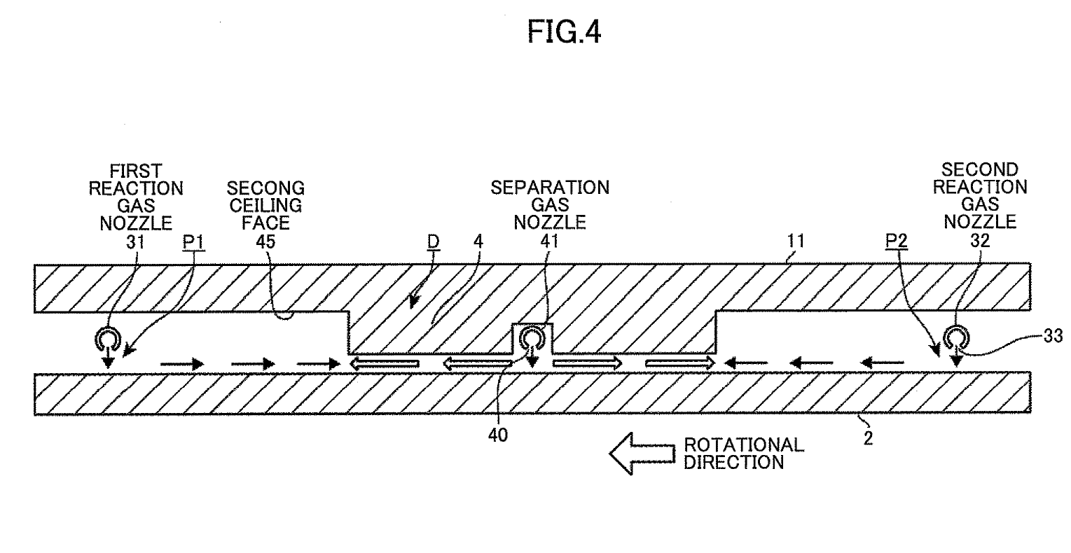

The sector-like portions 4 have a lower flat ceiling faces (first ceiling faces) 44 on both sides of the separation gas nozzles 41 and 42 in the outer peripheral direction. The first ceiling faces are the lower surfaces of the sector-like portions 4. Ceiling faces 45 (second ceiling faces) higher than the ceiling faces 44 are positioned on both sides of the ceiling faces 44 in the outer peripheral direction of the first ceiling faces 44. Referring to FIG. 4, the sector-like portions 4 function to form the narrow separating areas between the sector-like portions 4 and the rotary table 2 to thereby cause the separation gas to discharge onto sides of the processing areas P1 and P2. Therefore, the flow of the separation gas prevents the first reaction gas and the second reaction gas from intruding into the separating area D.

Said differently, when the rotary table 2 is rotated, along with the rotation of the rotary table, an atmosphere (the reaction gas) on the upstream side in the rotational direction is apt to be drawn into the separating area on the downstream side in the rotational direction. Further, if the separation gas contacts the reaction gas, the reaction gas is apt to diffuse via the atmosphere of the separation gas. Furthermore, a gas flow is generated depending on a pressure difference between the separation gas and the reaction gas. Therefore, in the embodiments, the gas flow rate in the separating area D is set so as to: (1) overcome the flow rate of the atmosphere drawing into the rotation of the rotary table and (2) form gas flows of the separation gas from the separating area D to the processing areas P1 and P2 thereby substantially preventing intrusion of the reaction gas even if the reaction gas slightly diffuses into the separating area D. In the following processing conditions, it was found by the inventors that the item (1) is dominant and influences more than the item (2) when the gas separating function with the separating area D is to be ensured as results of various tests and so on carried out by the inventor. Therefore, the flow rate of the separation gas discharged from the separating areas D into the processing areas P1 and P2 via the narrow areas is made greater than the flow rate of the atmosphere drawn into the rotation of the rotary table in the separating areas D.

Specifically, the flow rate of the atmosphere drawn into the downstream side of the rotation of the rotary table 2 is nearly equal to the peripheral speed obtained from the rotational speed or slower than the peripheral speed. Therefore, the flow rates of the separation gas discharged from the narrow area into the processing areas P1 and P2 are set faster than the peripheral speed in order to maintain the separating function of the separating area D. As described above, the flow rates of the first reaction gas and the second reaction gas are very small in comparison with the flow rate of the separation gas, and the rotational speed of the rotary table 2 is fast enough to be about 240 rpm. Therefore, the reaction gases discharged from the reaction gas nozzles 31 and 32 to the vacuum vessel 1 may be motionless relative to the rotating wafer W on the rotary table 2. Therefore, the flow rates of the reaction gases discharged from the reaction gas nozzle 31 and 32 are approximately zero.

Further, the atmosphere to be drawn into the separating area D by the rotation of the rotary table 2 receives resistance from exhaust gas flows heading members inside the vacuum vessel 1 and the exhaust port 61(62) described later. Therefore, the flow rate of the atmosphere actually becomes slower than the peripheral speed of the rotary table 2. However, for the simplicity of the calculation and for providing margins in the flow rates of the separation gases discharged from the separating area D to the processing areas P1 and 22 in consideration of the flow rate of the atmosphere, the flow rate of the atmosphere is assumed to be nearly equal to the peripheral speed of the rotary table 2 in the calculation.

The outer peripheral speed of the rotary table 2 on the outer periphery of the rotary table 2 is faster than the inner peripheral speed on the center side of the rotary table 2. The outer peripheral speed of the rotary table 2 on which a wafer W having a diameter of 300 mm is about three times faster than the inner peripheral speed on the center side of the rotary table 2. Therefore, if the flow rates of the separation gases discharged from the separating area D into the processing areas P1 and P2 are set to be the same value between the center side and the outer peripheral side of the rotary table, said differently if the flow rates of the separation gases are set so as to ensure the separating function with the separating area at the outermost periphery of the rotary table where the peripheral speed is maximum, the separation gas is excessively supplied to the center side of the rotary table 2. Therefore, with the embodiments of the present invention, in order to reduce the consumed amount of the separation gas as much as possible while ensuring the separating function with the separating area D with respect to the flow rate of the separation gas discharged from the separating area D to the processing areas P1 and P2, the rotational speed of the rotary table on the center side is set to be slower than the rotational speed of the rotary table on the outer peripheral side to reduce the supply amount of the separation gas in the center side in comparison with the outer peripheral side. A method of specifically setting the flow rate of the separation gas as to attain the above flow rate is described next. In the method, the separating area D is sectioned into two areas A1 and A2 from the center side of the rotary table 2 to the outer periphery side of the rotary table, and the flow rate of the separation gas in the area A1 is set smaller than the flow rate of the separation gas in the area A2.

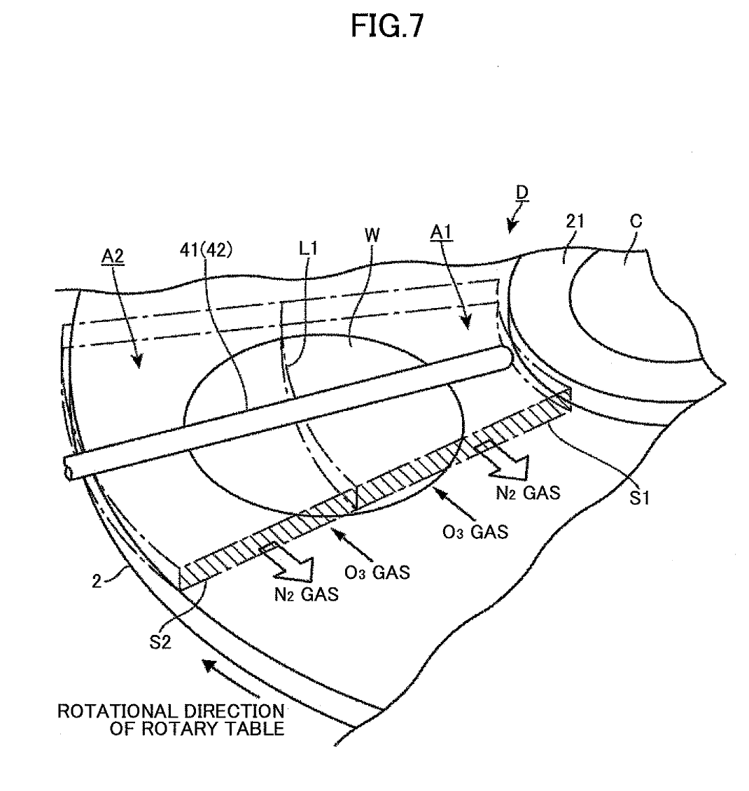

Referring to FIG. 5, a reference symbol “L1” is attached to a circular line connecting the centers of the five wafers W on the rotary table 2. An area of the rotary table on the center side of the line L1 is referred to as an area A1, which is surrounded by an imaginary vertical surface passing through the line L1, an outer peripheral surface of a ring-like 5 described later, the wafer W on the rotary table 2, and the sector-like portions 4. An area of the rotary table on the outer peripheral side of the line L1 is referred to as an area A2, which is surrounded by the imaginary vertical surface passing through the line L1, an imaginary vertical surface passing through the outer periphery of the rotary table 2, the wafer W on the rotary table 2, and the sector-like portions 4. Referring to FIG. 7, areas of side surfaces S1 and 52 facing the processing areas P1 and P2 on the upstream and downstream sides in the areas A1 and A2 are obtained. Further, if the rotational speed of the rotary table 2 is set to be 240 rpm, the maximum peripheral speeds of the rotary table 2 in the areas A1 and A2, said differently the peripheral speed at the line L1 (the maximum peripheral speed of the area A2) and the peripheral speed at the outer periphery of the rotary table 2 (the maximum peripheral speed of the area A2), are calculated. In FIG. 7, only the upstream side of the rotational direction of the rotary table 2 of both sides of the areas A1 and A2 is illustrated and the sector-like portion is omitted.

Next, the flow rates of the separation gases supplied to the separating areas D are set. For example, a process pressure is 1067 Pa (8 Torr) and a process temperature is 350° C. The volume of the separation gas in the vacuum vessel 1 under the above process pressure and process temperature is acquired. A part of the separation gas is discharged from the side surfaces Si, Si of the area A1 to the processing areas P1 and P2, and the other part of the separation gas is discharged from the side surfaces S2, S2 of the area A2 to the processing areas P1 and P2. Thus, a ratio between the flow rate of the separation gas in the areas A1 and the flow rate of the separation gas in the area A2 is set up. Subsequently, in the above processing conditions, various calculations are carried out while changing the flow rate of the separation gas supplied to the separation area D and the ratio so that the flow rate of the separation gas discharged from the side surfaces A1 and A2 become gradually larger than the maximum peripheral speeds of the rotary table 2 in the areas A1 and A2.

As the result of the calculations, the maximum peripheral speeds of the rotary table 2 in the areas A1 and A2 becomes about 7.8 m/s and about 12 m/s, respectively. For example, the flow rates of the separation gases supplied to the separating areas D are 10 slm, and a ratio between the flow rates of the separation gases allocated to the areas A1 and A2 are 1:2. As to the area A2, although the separation gas is discharged from the side surfaces S2, the separation gas is also slightly discharged from the separating area D via the area between the rotary table 2 and the bent portion 46 on the outer peripheral side of the outer periphery of the rotary table 2. Therefore, for example, a small amount of the flow rate of the gas supplied to the area A2 is subtracted as the flow rate discharged via the above outer periphery of the rotary table 2 in the calculation. Accordingly, the flow rate of the separation gas is set so that the flow rate of the separation gas discharged from the separating area is faster than the flow rate of the atmosphere drawn into the separating area of the upstream side. Therefore, the atmosphere is prevented from intruding into the separating area D from the downstream side of the separating area D.

Although the N2 gas is supplied from the separation gas supplying tube 51 to the center area C, the N2 gas is supplied to prevent the gases from being mixed via the center area C. The flow rate of the N2 gas supplied to the center area C is, for example, 1 slm, which is about 1/1 to 1/10 of the flow rate of the N2 gases supplied from the separation gas nozzles 41 and 42. Therefore, the separation gases heading the separating areas D from the center area C have extremely low flow rate being one-sixth (⅙) or less of the gas flow rate supplied from the separation gas nozzle 41 or 42. Said differently, since the separation gas supplied to the center area C outwardly flows along the periphery from the center area C, one-sixth (⅙: θ=60°/360°) of the gas tends to intrude into the separating areas D. However, the ceiling faces 44 are formed in the vicinity of the surface of the rotary table 2 in the separating area, and the ceiling faces 45 higher than the ceiling face 44 are formed on the processing areas P1 and P2, and the separation gas seldom tends to intrude from the center area C to the separating area D. Therefore, in consideration of the flow rate of the N2 gas supplied inside the vacuum vessel from the separation gas supplying tube 51, the flow rate of the N2 gas on the outer peripheral side of the rotary table 2 becomes greater than the flow rate of the N2 gas on the center side of the wafer W.

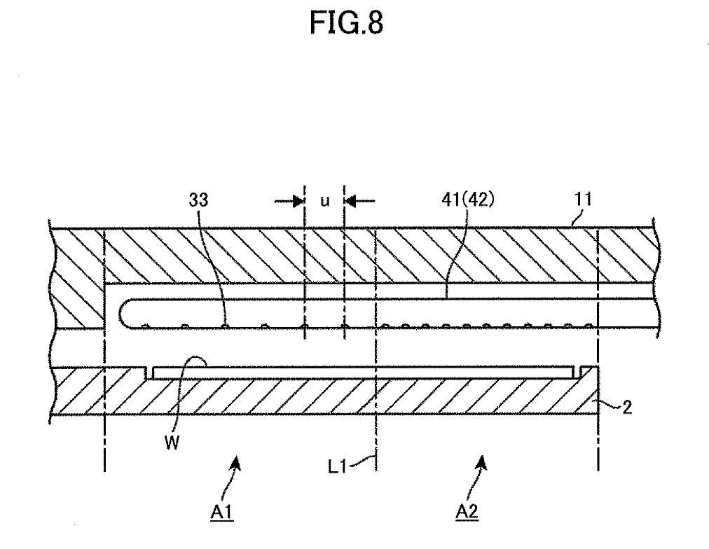

In order to attain the above-described flow rate of the N2 gas, said differently, to make the ratio of the flow rates of the separation gases supplied into the areas A1 and A2, the above-described gas discharge ports 33 are arranged in the separation gas nozzles 41 and 42. For example, referring to FIG. 8, the gas discharge ports 33 are arranged with an arrangement interval (pitch) u of 20 mm in the area A1, and the gas discharge ports 33 are arranged with an arrangement interval (pitch) u of 10 mm in the area A2.

When the arrangement interval u of the gas discharge ports 33 is set to have an equal interval along the longitudinal directions of the separation gas nozzles 41 and 42 (u: 10 mm), said differently, a ratio of the flow rate of the separation gases supplied into the areas A1 and A2 is 1:1, the flow rate of the separation gas is calculated as being 12.5 slm. This calculation is performed under the above processing conditions where the flow rates of the separation gases discharged from the side surfaces into the areas A1 and A2 become slightly greater than the maximum peripheral speeds. Therefore, by allocating the flow rates of the separation gases into the areas A1 and A2, it is possible to save the separation gases of 5 slm in the two separating areas D.

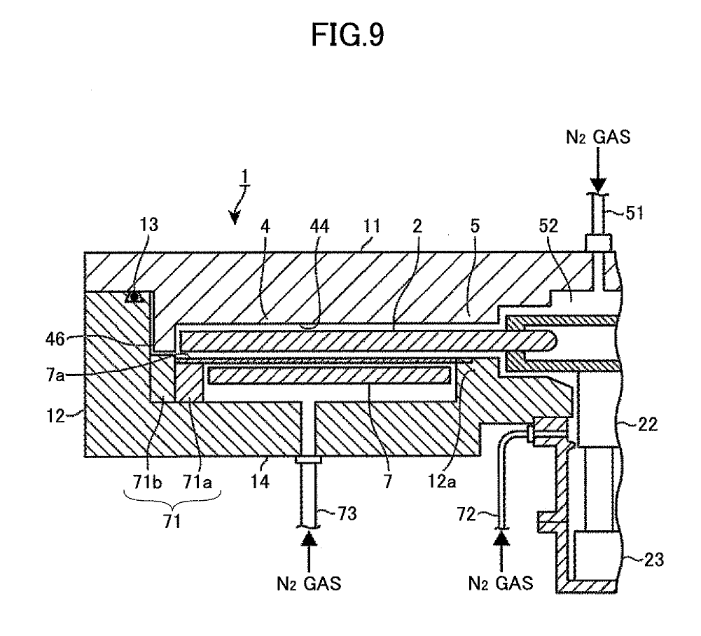

Subsequently, the vacuum vessel 1 is described again. Referring to FIG. 9, the ring-like portion 5 is provided on the lower surface of the ceiling 11 along the core unit 21 so as to face the core unit 21 of the rotary table 2 on the outer peripheral side of the core unit 21. The ring-like portion 5 is continuously formed from the rotation center side of the sector-like portion 4, and the lower surface of the ring-like portion 5 has the same height as the lower surface (the ceiling face 44) of the sector-like portion 4. Distances between the outer peripheral surface of the core unit 21 and the fore-ends of the nozzles 31, 32, 41 and 42 is, for example, 50 mm. Referring to FIG. 2 and FIG. 3, the ceiling 11 is horizontally cut at a position lower than the ceiling face 45 and higher that the separation gas nozzles.

As to the lower surface of the ceiling 11 of the vacuum vessel 1, said differently, the ceiling face viewed from wafer mounting areas (the recessed portions 24) of the rotary table 2, the first ceiling faces 44 and the second ceiling faces 45 higher than the first ceiling faces 44 extend in the peripheral direction. FIG. 1 is a vertical cross-sectional view for illustrating the higher ceiling face 45. FIG. 9 is a vertical cross-sectional view for illustrating the lower ceiling face 44. The outer peripheral portions (the outer peripheral side of the vacuum vessel 1) of the sector-like portions 4 form bent portions 46 which are bent into an L shape so as to face the outer edge surface of the rotary table 2 as illustrated in FIG. 2 and FIG. 9. The sector-like portion 4 is provided in the ceiling 11, and the sector-like portion 4 can be removed from the container body 12. Therefore, there is a narrow gap between the outer edge surface of the bent portion 46 and the container body 12. For example, the bent portions 46 are formed to prevent the reaction gases from intruding into the separating areas from the outsides thereby preventing from mixture of the reaction gases as in the sector-like portions 4. The gap between the inner peripheral surfaces of the portions 46 and the outer edge surface of the rotary table 2 and the gap between the outer edge surfaces of the bent portions 46 and the container body 12 may be substantially equal to the gap between the surface of the rotary table 2 and the first ceiling face 44 (the height of the ceiling face 44 relative to the surface of the rotary table 2).

For example, the inner peripheral wall of the container body 12 is vertically formed in the vicinity of the outer edge surfaces of the bent portions 46 in the separating areas D as illustrated in FIG. 9. For example, in areas other than the separating areas D, the inner peripheral wall is outwardly and downwardly recessed in a rectangular shape from a portion facing the outer edge surface of the rotary table 2 down to the bottom surface portion 14 as illustrated in FIG. 1. The recessed portion of the inner peripheral wall of the container body 12 in the first processing area P1 is referred to as a first exhaust area E1, and the recessed portion of the inner peripheral wall of the container body 12 in the second processing area P2 is referred to as a second exhaust area E2. In the bottom portions of the first and second exhaust areas E1 and E2, a first exhaust port 61 and a second exhaust port 62 are formed, respectively. The first and second exhaust ports 61 and 62 may be connected to a vacuum pump 64 being a vacuum ejecting mechanism via the exhaust tubes 63. Referring to FIG. 1, a reference symbol 65 designates a pressure adjusting unit.

Referring to FIG. 1 and FIG. 9, a heater unit 7 being a heating means is provided in a space between the rotary table 2 and the bottom surface portion 14 of the vacuum vessel 1. The heater unit 7 heats the wafer W on the rotary table 2 via the rotary table 2 to make the wafer W be a temperature determined by the processing conditions. A cover member 71 shaped like a ring is provided so as to surround the heater unit 7 along the entire periphery of the heater unit 7 to prevent the gas from intruding into the lower area of the rotary table by separating an atmosphere in an upper space of the rotary table and the exhaust areas E1 and E2 from an atmosphere including the heater unit 7. The cover member 71 includes an inner member 71a provided on a lower and outer peripheral end side of the rotary table 2 as if the outer edge surface of the rotary table 2 outwardly and downwardly faces the cover member 71 and an outer member 71b provided between the inner member 71a and the inner wall surface of the vacuum vessel 1. The outer member 71b is partly cut to connect the exhaust ports 61 and 62 to the upper area of the rotary table 2 on upper sides of the exhaust ports 61 and 62. For example, the outer member 71b is cut like an arc to form the exhaust areas E1 and E2. The upper surface of the outer member 71b is arranged so as approach the bent portion 46 from a lower side of the bent portion.

A part of the bottom surface portion 14 closer to the rotation center than the area where the heater unit 7 is arranged has a ring-like portion 12a upwardly protruding toward the lower surface of the core unit 21 of the rotary table 2. A narrow space is provided between the ring-like portion 12a and the core unit 21. A gap between the inner peripheral surface of a through hole of the rotary shaft 22 penetrating through the bottom surface portion 14 and the rotary shaft 22 is small. The narrow space and the small gap are connected to the inside of the casing 20. A purge gas supplying tube 72 for supplying a purge gas of a N2 gas to the narrow space and the small gap is provided in the casing 20. An opening of the purge gas supplying tube 72 is connected to the narrow space and the small gap. Purge gas supplying tubes 73 for purging the areas of the heater units 7 are provided in plural positions under the heater units in a peripheral direction are provided in the bottom surface portion 14 of the vacuum vessel 1. Openings of the purge gas supplying tubes 73 are connected to the areas of the heater units 7. Cover members 7a are provided between the heater units 7 and the rotary table 2 to prevent the gas from intruding into the area of the heater unit 7. The cover member 7a may cover (connect) an opening between the inner peripheral wall of the outer member 71b and an upper end portion of the ring-like portion 12a. For example, the cover member 7a is made of quartz.

A separation gas supplying tube 51 is connected to a center portion of the ceiling 11 of the vacuum vessel 1. The separation gas of a N2 gas is supplied to a space 52 between the ceiling 11 and the core unit 21. The separation gas supplied to the space 52 is discharged toward the outer periphery of the rotary table 2 along the surface on the side of the wafer mounting area via the narrow gap 50 between the ring-like portion 5 and the rotary table 2. Because the space surrounded by the ring-like portions 5 is filled with the separation gas, it is possible to prevent the reaction gases (the Si containing gas and O3 gas) from mixing between the first processing area P1 and the second processing area P2 via the center portion of the rotary table 2.

Further, a delivery port 15 for delivering and receiving the wafers W being the substrate between an external delivery arm and the rotary table 2 as illustrated in FIG. 2 and FIG. 3 is formed in the side wall of the vacuum vessel 1. The delivery port 15 is opened and closed by a gate valve (not illustrated). Further, lift pins for lifting the wafers from these back surfaces and lifting mechanisms (not illustrated) are provided in the recessed portions 24 being the wafer mounting area of the rotary table 2. The wafers W are delivered and received as a position corresponding to the delivery port 15. Therefore, the lift pins penetrate the recessed portions 24 from a lower surface of the rotary table 2 to bring the wafers W to the position where the wafers W are delivered and received with the delivery arm 10.

The film forming apparatus includes a control unit 100 having a computer for controlling an entire operation of the film forming apparatus. A program for carrying out the film forming process is stored in a memory of the control unit 100. The program is installed in the control unit 100 from a memory unit 101 being a recording medium such as a hard disk, a compact disk, a magnet-optical disk, a memory card, and a flexible disk.

Next, functions of the embodiments of the present invention are described. First, a gate valve (not illustrated) is opened. The wafer W is delivered into or received from the recessed portion 24 in the rotary table 2 with the delivery arm 10 from the outside via the delivery port 15. When the recessed portion 24 is stopped at a position facing the delivery port 15, the lift pin (not illustrated) lifts up or down from the bottom side of the vacuum vessel through the through hole in the bottom surface of the recessed portion 24 to deliver or receive the wafer W. The delivery and receipt of the wafers W are carried out by intermittently rotating the rotary table 2 to thereby mount the wafers W in the five recessed portions 24 in the rotary table 2. Subsequently, the gate valve is closed to evacuate the inside of the vacuum vessel 1 by a vacuum pump 64. At the same time, the wafers W are heated to be 350° C. while the rotary table 2 is rotated at 240 rpm in the clockwise direction. Subsequently, the Si containing gas and the O3 gas are discharged from the reaction gas nozzles 31 and 32 at flow rates of, for example, 100 sccm and 10 slm, respectively. At the same time, the separation gases being the N2 gases are discharged from the separation gas nozzles 41 and 42 at a flow rate of, for example, 10 slm. The N2 gases are discharged from the separation gas supplying tube 51 and the purge gas supplying tube 72 at flow rates of, for example, 1 slm to 3 slm and 10 slm, respectively. Thus, the pressure adjusting unit 65 adjusts the inner pressure of the vacuum vessel 1 to be a predetermined process pressure of, for example, 1067 Pa (8 Torr).

When the rotary table rotates, the Si containing gas in absorbed on the surface of the wafer W in the first processing area P1, and the Si containing gas absorbed in the wafer W in the second processing area P2 is oxidized to thereby form a film of a reaction product having one or plural molecular layers of silicon oxide film being a thin film component. By laminating the reaction products, the thin film is formed. At this time, the reaction gas tends to intrude into the separating area D along with rotation of the rotary table 2. However, since the gas discharge port 33 of the separation gas nozzles 41 and 42 and the flow rate of the separation gas are set as described, an intrusion of the reaction gas into the separating area D of the reaction gas can be prevented.

In preventing the intrusion of the reaction gas into the separating area D, the supply amount of the separation gas is set to be as small as possible as described above. Said differently, the supply amount of the reaction gas on the center side of the rotary table 2 is set to be smaller than the supply amount of the reaction gas on the outer peripheral side. Therefore, the Si containing gas is prevented from being diluted in the processing area P1. Therefore, in the processing area P1, a contact time between the wafer W and the Si containing gas becomes sufficiently long, and the concentration of the Si containing gas which the wafer W contacts is thereby maintained to be high during this sufficiently long contact time. Then, the amount of the Si containing gas absorbed on the surface of the wafer W becomes a predetermined value. Further, since the dilution of O3 gas with the separation gas is suppressed in the processing area P2, the Si containing gas absorbed in the wafer W is well oxidized. Therefore, it is possible to prevent residual impurities in the film, for example.

Further, since the N2 gas being the separation gas is supplied to the center area C, the gases are exhausted so that the O3 gas, the Si containing gas, and the processing gas are not mutually mixed as illustrated in FIG. 10. Since the lower side of the rotary table 2 is purged by the N2 gas, the gas that flows into the exhaust area E does not pass through the lower side of the rotary table 2 and does not flow into the supply area of the O3 gas.

With the above embodiments, in rotating the rotary table 2 so that the wafers W sequentially pass through the processing areas P1 and P2 via the separating areas D, the gas discharge ports of the separation gas nozzles are arranged to increase the supply gas amount of the separation gas on the outer peripheral side of the rotary table 2 more than the supply gas amount of the separation gas on the center side of the rotary table 2. At the same time, the flow rates of the separation gases discharged from the separating area D to the processing areas P1 and P2 are set to be slightly faster than the maximum peripheral speeds of the rotary table 2 in the area A1 and the area A2, respectively. Therefore, it is possible to prevent an excessive supply of the separation gas on the center side, and therefore the consumed amount of the separation gas can be suppressed while still ensuring the separating function with the separating area D. Therefore, dilution of the reaction gases can be prevented to thereby enable forming a thin film at the predetermined film forming rate. Even if the rotational speed of the rotary table 2 is set to be as high as, for example, 240 rpm or the process pressure is set as high as, for example, about 2666 Pa (20 Torr), the predetermined high film forming rate is obtainable. By enabling widening the range of setting the film forming rate, the process margin can be expanded.

Further, by suppressing the consumed amount of the separation gas, it is possible to suppress a load on the vacuum pump 64 exhausting the separation gas. Therefore, an expensive member (a vacuum pump 64) can be rendered unnecessary to thereby reduce the cost for the film forming apparatus. Furthermore, if an exhausting capability of the vacuum pump has a margin by suppressing the consumed amount of the separation gas, the inside of the vacuum vessel 1 may be set to be high vacuum of, for example, about 133 Pa (1 Torr) to thereby carry out the film forming process. Further, since the amount of consuming the separation gas is suppressed, the cost of the separation gas may be decreased.

Furthermore, the peripheral speed of the rotary table 2 is used for convenience as the flow rate of the atmosphere to be drawn into the separating area as described above, so that the flow rate of the separation gas may be simply calculated. Furthermore, since the narrow areas are formed on the both sides of the separation gas nozzles 41 and 42, the separation gas supplied to the separating area D flows toward the processing areas P1 and P2 in a laminar airflow state. Therefore, the flow rate can be easily calculated as described above.

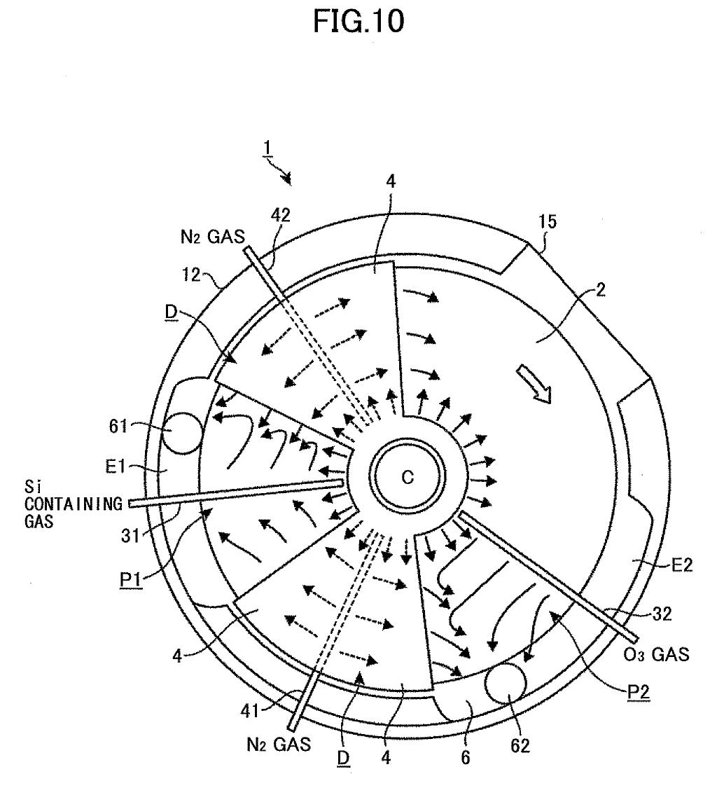

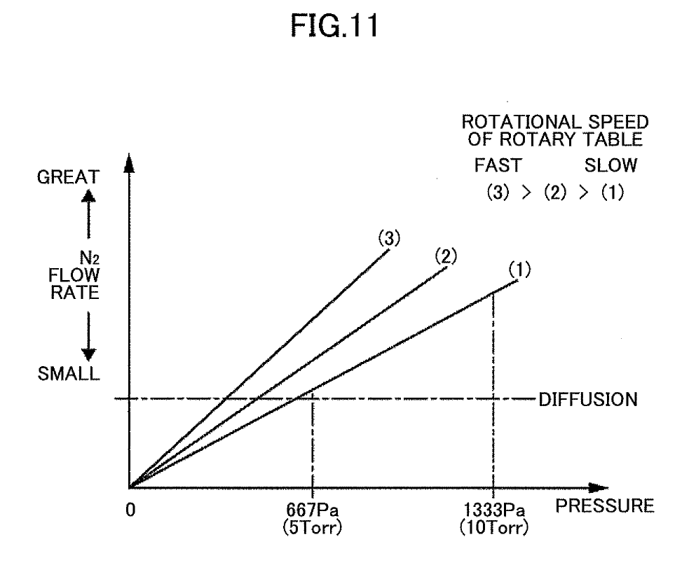

FIG. 11 is a graph illustrating the flow rate of a separation gas for preventing an outer atmosphere (the reaction gas) from intruding into the separating area D relative to the rotational speed of the rotary table 2 and the pressure inside the vacuum vessel 1. The faster the rotational speed of the rotary table is, the faster the flow rate of the atmosphere intruding into the separating area D along with the rotation of the rotary table. Therefore, the flow rate of the separation gas for preventing the atmosphere from intruding into the separation area also increases. The higher the pressure inside the vacuum vessel 1, the less the separation gas supplied into the vacuum vessel 1 expands. Therefore, the flow rate of the separation gas for preventing the atmosphere from intruding into the separating area D also increases in a similar manner thereto. Therefore, an effect of suppressing the consumed amount of the separation gas by decreasing the flow rate of the separation gas on the center side of the rotary table 2 less than the flow rate of the separation gas on the outer peripheral side of the rotary table 2 becomes conspicuous as the rotational speed of the rotary table 2 becomes faster or the pressure inside the vacuum vessel 1 becomes higher, said differently, as the conditions are satisfied to obtain a higher film forming rate 1. Preferable processing conditions for the embodiments of the present invention are the rotational speed of the rotary table 2 of 120 rpm or more and the pressure inside the vacuum vessel 1 of 133 Pa (1 Torr) or more. As illustrated by a dot chain line in FIG. 11, under a condition in which the rotational speed of the rotary table 2 is slow and the pressure inside the vacuum vessel 1 is low, gas diffusion dominantly affects separation of the gases in comparison with gas flow rates. Said differently, if the separation gas is discharged from the separating area D at a flow rate faster than the flow rate of the atmosphere intruding into the separating area D, the atmosphere tends to diffuse via an area in which the separation gas diffuses. Therefore, it is preferable to apply the embodiments of the present invention under the above-described processing conditions.

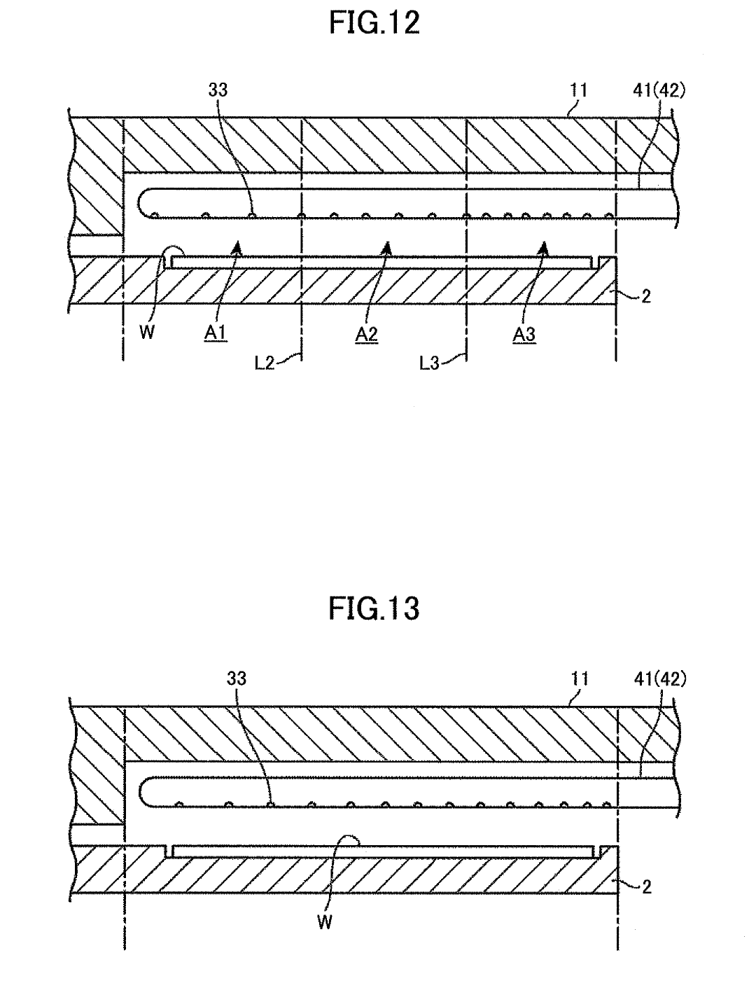

In the above example, the two areas A1 and A2 are provided to reduce the supply amount of the separation gas on the center side of the rotary table 2 less than the supply amount of the separation gas on the outer peripheral side of the rotary table 2. However, the areas A1 and A2 may be three or more. FIG. 12 illustrates three areas A1, A2 and A3 from the center side of the rotary table 2 to the outer peripheral side of the rotary table 2. A border line L2 between the areas A1 and A2 and a border line L3 between the areas A2 and A3 are positioned at one-third (⅓) and two-thirds (⅔) of the diameter of the wafer W in a direction from the center side of the rotary table 2 to the outer peripheral side of the rotary table 2, respectively. In the areas A1, A2 and A3, the arrangement intervals u of the gas discharge ports 33 of separation gas nozzles 41 and 42 are 30 mm, 20 mm and 10 mm, respectively. In this case, since the gas flow rates can be allocated to the three areas A1, A2 and A3 in conformity with the maximum peripheral speeds of the rotary table 2, the consumed amount of the separation gas can further be reduced.

Referring to FIG. 13, the arrangement intervals u of the gas discharge ports 33 of the separation gas nozzles 41 and 42 may be gradually narrowed in the direction from the center side of the rotary table 2 to the outer peripheral side of the rotary table 2. Said differently, the arrangement interval u may be 25 mm on the center side of the rotary table 2 and the arrangement interval u may be 5 mm on the outer peripheral side of the rotary table 2. For example, the arrangement intervals u may be narrowed by 1 mm for every gas discharge port 33 in the direction from the center side of the rotary table 2 to the outer peripheral side of the rotary table 2. In this case, the gas flow rates can be minutely allocated to a radius direction of the rotary table 2 in conformity with the peripheral speeds at positions in the radius direction. Therefore, the consumed amount of the separation gas can further be reduced.

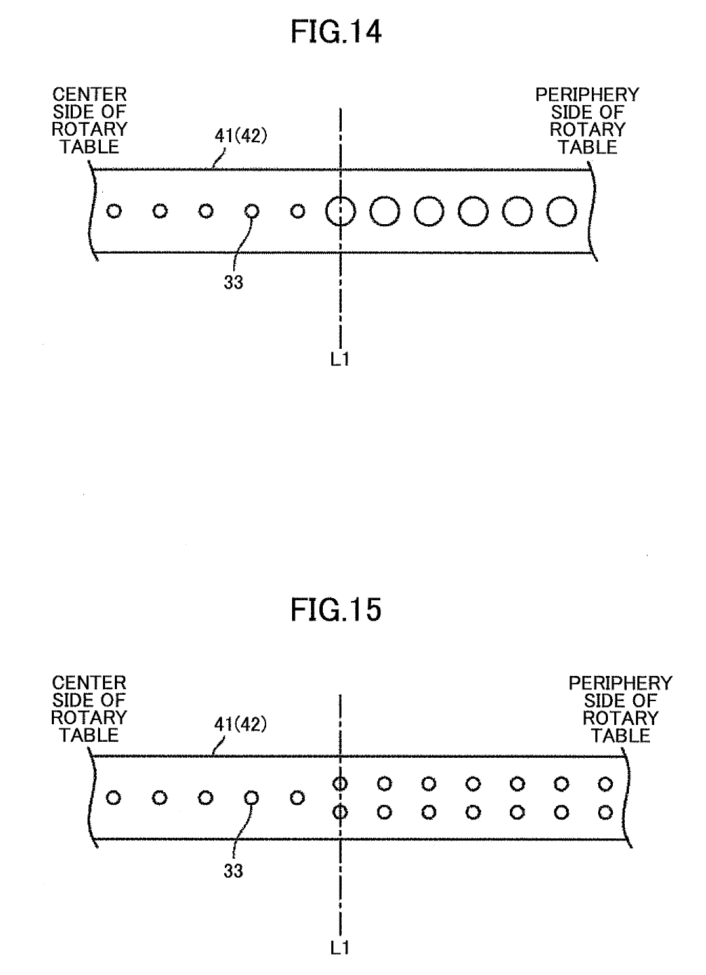

In the above example, the arrangement intervals u of the gas discharge ports 33 are adjusted in allocating the supply amount of the separation gas. However, opening diameters of the gas discharge ports 33 may be adjusted in addition to or instead of the adjustment of the arrangement intervals u. FIG. 14 illustrates an example in which the gas discharge ports 33 are arranged with an equal arrangement interval u, for example 10 mm, along the longitudinal directions of the separation gas nozzles 41 and 42, an opening diameter of the gas discharge ports 33 on the center side of the rotary table 2 is, for example, 0.19 mm, and an opening diameter of the gas discharge ports 33 on the outer peripheral side of the rotary table 2 is, for example, 0.27 mm. Said differently, a ratio of the opening diameter of the gas discharge port 33 on the center side of the rotary table 2 and the opening diameter of the gas discharge ports 33 on the outer peripheral side of the rotary table 2 is 1:2. FIG. 14 schematically illustrates a part of the separation gas nozzle 41 or 42 viewed from the lower side of the separation gas nozzle 41 or 42. FIG. 14 schematically illustrates a part of the separation gas nozzle 41 or 42 viewed from the lower side of the separation gas nozzle 41 or 42.

Further, as illustrated in FIG. 15, the equal arrangement intervals u of the gas discharge ports 33 may be, for example, 10 mm along the longitudinal directions of the separation gas nozzles 41 and 42, and the opening diameters of the gas discharge ports 33 may be set to be equal along the longitudinal directions of the separation gas nozzles 41 and 42. Densities of arranging the gas discharge ports 33 on the center side and the outer peripheral side of the rotary table may be changed. Referring to FIG. 15, the gas discharge ports 33 on the center side of the rotary table 2 are arranged on one line, and the gas discharge ports 33 on the outer peripheral side of the rotary table 2 are arranged on two parallel lines. The directions of the two lines are the longitudinal direction of the separation gas nozzles 41 and 42 and the two lines are arranged in a direction perpendicular to the longitudinal direction of the separation gas nozzles 41 and 42. When the supply amount of the separation gas on the center side is made smaller than the supply amount of the separation gas on the outer peripheral side, the supply amounts maybe adjusted by combining the arrangement intervals u of the gas discharge ports, the opening diameters of the gas discharge ports, and the density of arranging the gas discharge ports.

The nozzles 41 and 42 extending from the outer peripheral side of the rotary table 2 to the center side of the rotary table 2 are provided to supply the separation gas. However, separation gas supplying units (gas discharge ports or a gas shower head in substantially a disk-like shape) for supplying separation gases on the outer peripheral side and the center side of the ceiling face of the vacuum vessel 1, respectively, can also be used. In this case, the flow rates of the separation gases on the outer peripheral side and the center side from the separation gas supplying units can be independently adjusted. In this case, the separation gases supplied from the separation gas supplying units to the separating areas D may be prevented more from flowing into the upstream sides with the above-described narrow areas and simultaneously diffuses more in radius directions of the rotary table 2 as the positions of the separation gas becomes closer the processing areas P1 and P2 whereby the separation gases are discharged into the processing areas P1 and P2 along the radius directions. According to the embodiments of the present invention, the flow rate of the separation gas, which is supplied from the gas supplying unit provided on the ceiling face of the vacuum vessel 1 to face the wafer W, on an inner (center) side of the rotary table 2 is set to be smaller than the flow rate of the separation gas on an outer (outer peripheral) side. A separation gas supplied to a center portion of the vacuum vessel 1 from the known separation gas supplying tube 51 is regarded by the inventors as a different separation gas from the separation gas on the inner (center) side of the rotary table 2.

In the above description, the rotary table 2 is rotated relative to the nozzles 31, 32, 41 and 42. However, the rotary table 2 maybe stopped and the nozzles 31, 32, 41 and 42 may be rotated relative to the rotary table 2. Further, substantially box-like covers having an opening on their lower surfaces may be provided to cover the reaction gas nozzles 31 and 32 from an upper surface side, both side surfaces in the rotational direction and the center area C to thereby prevent the separation gases from diffusing into the processing areas P1 and P2. The separation gas is not limited to a nitrogen (N2) gas and may be an inert gas such as an argon (Ar) gas.

According to the embodiments of the present invention, the separating gases are supplied to increase the flow rate on the outer peripheral side more than the flow rate on the center side of the vacuum vessel 1 while rotating the loading table relative to the plural reaction gas supplying units and the separating areas so the substrates are sequentially positioned inside the processing areas after positioning inside the separating areas in the vacuum vessel. Therefore, it is possible to prevent an excessive supply of the separation gas on the center side, and therefore the consumed amount of the separation gas can be suppressed while ensuring the separating function with the separating area D.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A film forming apparatus that produces a thin film by repeating cycles of sequentially supplying plural kinds of reaction gases, the film forming apparatus comprising:
a loading table which is provided in a vacuum vessel and has substrate mounting areas for mounting substrates thereon;
a plurality of reaction gas supplying units arranged in a peripheral direction with intervals located between the reaction gas supplying units and configured to supply the plural kinds of the reaction gases onto the substrates in the substrate mounting areas;
separating areas provided between the processing areas and configured to separate atmospheres of the processing areas to which the reaction gases are supplied;
separation gas supplying units which are configured to supply separation gases to center side separation areas on a center side of the separation areas and outer peripheral side separation areas on an outer peripheral side of the separation areas inside the separation areas to render a supply amount to the outer peripheral side separation areas greater than a supply amount to the center side separation areas;
a ceiling face which surrounds narrow areas together with the loading table to enable the separation gases to flow from the separating areas to the processing areas along the center side separation areas and the outer peripheral side separation areas;
a vacuum ejecting mechanism configured to form a vacuum inside the vacuum vessel; and
a rotary mechanism which rotates the loading table relative to the reaction gas supplying units and the separating areas.

2. The film forming apparatus according to claim 1,
wherein the separation gas supplying units are provided to face the substrate mounting areas and have gas nozzles extending along the center side separation areas and the outer peripheral side separation areas,
the gas nozzles have a plurality of gas discharge ports for discharging the separation gases to the substrate mounting areas along longitudinal directions of the gas nozzles with an interval between the gas discharge ports, and
at least one of the interval between the gas discharge ports, opening diameters of the gas discharge ports, and densities of arranging the gas discharging ports are set to render the supply amount to the outer peripheral side separation areas to be greater than the supply amount to the center side separation areas.

3. A film forming method for forming a thin film by repeating a plurality of cycles of sequentially supplying plural kinds of reaction gases in a vacuum atmosphere, the film forming method comprising:
loading substrates on substrate mounting areas for mounting the substrates thereon, the substrate mounting areas being provided inside a vacuum vessel;
forming a vacuum inside the vacuum vessel by evacuating the vacuum vessel;
supplying separation gases to separating areas located between processing areas into which the reaction gases are supplied to render a supply amount to outer peripheral side separation areas on an outer peripheral side of the separation areas to be greater than a supply amount to center side separation areas on an outer peripheral side of the separation areas;
supplying the plural kinds of reaction gases onto the substrate mounting areas from a plurality of reaction gas supplying units which are arranged in a peripheral direction with intervals between the reaction gas supplying units;
separating atmospheres of the processing areas via narrow areas surrounding a ceiling face and a loading table inside the separating areas by discharging the separation gases from the separating areas to the processing areas along the outer peripheral side separation areas and the center side separation areas; and
rotating the loading table relative to the reaction gas supplying units and the separating areas thereby sequentially positioning the substrates in the processing areas via the separating areas.

4. The film forming method according to claim 3,
wherein a pressure inside the vacuum vessel is 133 Pa or more, and
a rotational speed of rotating the loading table relative to the reaction gas supplying units and the separating areas is 20 rpm or more.

5. A computer-readable, non-transitory medium storing a program that is used in a film forming apparatus that produces a thin film by repeating cycles of sequentially supplying plural kinds of reaction gases and causes a target computer to perform a procedure, the procedure comprising:
loading substrates on substrate mounting areas for mounting the substrates thereon, the substrate mounting areas being provided inside a vacuum vessel;
forming a vacuum inside the vacuum vessel by evacuating the vacuum vessel;
supplying separation gases to separating areas between processing areas into which the reaction gases are supplied to render a supply amount to outer peripheral side separation areas on an outer peripheral side of the separation areas to be greater than a supply amount to center side separation areas on an outer peripheral side of the separation areas;
supplying the plural kinds of the reaction gases onto the substrate mounting areas from a plurality of reaction gas supplying units which are arranged in a peripheral direction with intervals between the reaction gas supplying units;
separating atmospheres of the processing areas via narrow areas surrounding a ceiling face and a loading table inside the separating areas by discharging the separation gases from the separating areas to the processing areas along the outer peripheral side separation areas and the center side separation areas; and
rotating the loading table relative to the reaction gas supplying units and the separating areas to sequentially positioning the substrates in the processing areas via the separating areas.

6. The computer-readable, non-transitory medium according to claim 5,
wherein a pressure inside the vacuum vessel is 133 Pa or more, and
a rotational speed of rotating the loading table relative to the reaction gas supplying units and the separating areas is 20 rpm or more.
